(19) United States
(12) Patent Application Publication
(10) Pub. No.: US 2013/0207078 A1
(43) Pub. Date: Aug. 15, 2013

(54) InGaN-Based Double Heterostructure Field Effect Transistor and Method of Forming the Same

(71) Applicant: Kopin Corporation, (US)

(72) Inventors: Oleg Laboutin, South Easton, MA (US); Yu Cao, Norwood, MA (US); Wayne Johnson, Easton, MA (US)

(73) Assignee: KOPIN CORPORATION, Taunton, MA (US)

(21) Appl. No.: 13/745,046

(22) Filed: Jan. 18, 2013

Related U.S. Application Data
(60) Provisional application No. 61/588,014, filed on Jan. 18, 2012.

(51) Int. Cl. H01L 29/15; H01L 21/02; H01L 29/205

(52) U.S. Cl. CPC H01L 29/151; H01L 29/205; H01L 21/02507
USPC 257/20; 257/76; 438/478

(57) ABSTRACT

A double heterojunction field effect transistor (DHFET) includes a substrate, a buffer layer consisting of GaN back-barrier buffer layer formed on the substrate, a channel layer consisting of an InₓGa₁₋ₓN ternary alloy in one embodiment, and in another embodiment, InGaN/GaN superlattice (SL) formed on the GaN back-barrier buffer layer opposite to the substrate. A GaN spacer layer is formed on the InₓGa₁₋ₓN or InGaN/GaN superlattice channel layer opposite to the GaN buffer layer and a carrier-supplying layer consisting of an Al_{1-y}In_{y}N ternary alloy is formed on the GaN spacer layer opposite to the channel layer. A preferred thickness of the GaN spacer layer is less than about 1.5 nm. The InGaN/GaN SL preferably includes 1 to 5 InGaN—GaN pairs and a preferred thickness of the InGaN layer in the InGaN/GaN SL is equal to or less than about 0.5 nm. A two-dimensional electron gas is formed at the interface between the InₓGa₁₋ₓN or InGaN/GaN SL channel and GaN spacer layers.

### RELATED APPLICATIONS

This application claims the benefit of U.S. Provisional Application No. 61/588,014, filed Jan. 18, 2012, the relevant teachings of which are incorporated herein by reference in their entirety.

### BACKGROUND OF THE INVENTION

The present invention relates to double heterojunction field effect transistors that incorporate nitride based active layers and contain a high mobility two-dimentional electron gas.

While GaN-based field effect transistors (FET) are very promising both in terms of underlying material properties and demonstrated device results, fundamental physical limitations exist when scaling conventional GaN devices to deep submicron dimensions necessary to realize their potential for ultra-high power and ultra-high frequency operation. Two dimensions of the nitride transistor structure are particularly essential.

These are the barrier and channel thicknesses which have to be minimized to achieve high performance. For a conventional AlGaN/GaN FET structure, the two-dimensional electron gas density (2DEG) region in the channel layer rapidly decreases with decreasing thickness of the AlGaN barrier. Therefore, the barrier thickness can not be less than about 15-20 nm. The thickness of the GaN channel in such structures is not well defined following the width of the triangular quantum well at the AlGaN/GaN interface which in turn varies significantly with applied gate bias. It has been reported that the polarization charge at a lattice matched Al_{0.83}In_{0.17}N/GaN interface can be over twice that of conventional AlGaN/GaN (J. Kuzmik, “Power Electronics on InAlN/(In)GaN: Prospect for a Record Performance,” IEEE Electron Device Letters 22, 510 (2001)). While the Al_{0.83}In_{0.17}N barrier thickness can be significantly thinner than in the conventional structure. Indeed, the Al_{0.83}In_{0.17}N-based FET structures with barrier thickness of only 6-11 nm demonstrated marked improvements in drain currents (H. Wang, J. W. Chung, X. Gao, S. Guo, and T. Palacios, “Al2O3 passivated InAlN/GaN HEMTs on SiC substrate with record current density and transconductance”, Phys. Status Solidi C, 7, 2440 (2010)) and cut-off frequencies (D. S. Lee, X. Gao, S. Guo, D. Kopp, P. Fey, and T. Palacios, “300-GHz InAlN/GaN HEMTs With InGaN Back Barrier,” IEEE Electron Device Lett. 32, 1525 (2011)) when compared to the conventional AlGaN/GaN FET. However, these devices still lack control of the channel thickness because the 2DEG is formed in GaN, the same material as the buffer layer, and therefore suffer from short-channel effects (D. S. Lee, X. Gao, S. Guo, D. Kopp, P. Fey, and T. Palacios, “300-GHz InAlN/GaN HEMTs With InGaN Back Barrier,” IEEE Electron Device Lett. 32, 1525 (2011)) and leakage currents (J. Song, F. J. Xu, X. D. Yan, F. Lin, C. C. Huang, L. P. You, T. J. Yu, X. Q. Wang, B. Shen, K. Wei, and X. Y. Liu, “High conductive gate leakage current channels induced by In segregation around screw- and mixed-type threading dislocations in lattice-matched InAlN/GaN heterostructures,” Appl. Phys. Lett. 97, 232106 (2010)).

Two concepts have been previously proposed to form an energy barrier on the side of the nitride-based FET channel opposite the carrier-supplying barrier. First, an AlGaN buffer layer with Al composition of 0.04 has been synthesized directly on a substrate to form a back-barrier at the interface with GaN channel (D. S. Lee, X. Gao, S. Guo, and T. Palacios, “InAlN/GaN HEMTs with AlGaN back-barriers,” IEEE Electron Device Lett. 32, 617 (2011)). This structure suffers from poor material quality of the AlGaN buffer layer. Second, a thin InGaN layer with low In concentration has been inserted between both the GaN-based buffer and channel layers (J. Liu, Y. Zhu, K. M. Lau, and K. J. Chen, “AlGaN/GaN/InGaN/GaN DH-HEMTs with an InGaN notch for enhanced carrier confinement,” IEEE Electron Device Lett. 27, 10 (2006)). Due to the stress-related piezoelectric field in direction from the buffer to the top barrier, the conduction band of InGaN inclines towards lower energies lowering conduction band in the GaN channel with respect to that in the GaN buffer. Thus, the energy barrier is created in spite of a narrow-band-gap nature of InGaN. The problem with such a InGaN back-barrier is that, under negative gate bias, the high electron concentration can be injected from channel into the InGaN layer screening piezoelectric field and thus removing energy barrier on the back side of the channel. At the same time, a second conductive channel can be formed in the InGaN layer which can degrade device RF performance.

A narrow band gap InGaN surrounded by wider-band gap materials has been previously employed to form a Al_{0.83}In_{0.17}N-based double heterojunction field effect transistor (DHFET) structures (J. Xie, J. H. Leach, X. Ni, M. Wu, R. Shimada, U. Ozgur, and H. Morkoc, “Electron mobility in InGaN channel heterostructure field effect transistor structures with different barriers,” Appl. Phys. Lett. 91, 262102 (2007)).

The GaN buffer layer below the InGaN channel served as a back-barrier confining 2DEG inside InGaN. The spontaneous polarization charge difference and lattice mismatch between the Al_{1-y}In_{y}N and Ga₁₋ₓInₓN layers created a 2DEG which accumulated at the Al_{1-y}In_{y}N/Ga₁₋ₓInₓN interface. A wide range (0<x≦1) of In concentration in the Ga₁₋ₓInₓN channel has also been explored in the AlGaN-based DHFET structures (H. Ikki, Y. Isobe, D. Iida, M. Iwaya, T. Takeuchi, S. Kamiyama, I. Akasaki, H. Amano, A. Bandoh and T. Udagawa, “AlGaN/InGaN/GaN heterostructure field-effect transistor”, Phys. Status Solidi A 208, 1614 (2011)). However, structures using both Al_{0.83}In_{0.17}N and AlGaN barriers have revealed low electron mobility when compared to FETs with a GaN channel. This has been attributed to alloy disorder in the narrow band-gap InGaN and to barrier-channel interface roughness (J. Xie, J. H. Leach, X. Ni, M. Wu, R. Shimada, U. Ozgur, and H. Morkoc, “Electron mobility in InGaN channel heterostructure field effect transistor structures with different barriers,” Appl. Phys. Lett. 91, 262102 (2007); (H. Ikki, Y. Isobe, D. Iida, M. Iwaya, T. Takeuchi, S. Kamiyama, I. Akasaki, H. Amano, A. Bandoh and T. Udagawa, “AlGaN/InGaN/GaN heterostructure field-effect transistor,” Phys. Status Solidi A 208, 1614 (2011)).

In order to further improve the performance of InGaN-based FETs, it is desirable to reduce or eliminate the above-referenced problems

### SUMMARY OF THE INVENTION

The present invention provides high-performance InGaN-based DHFETs with improved 2DEG mobility and reduced leakage current. A DHFET constructed in accordance with the present invention comprises a substrate, a GaN back-barrier buffer layer formed on the substrate, and having a nucleation layer between the substrate and the GaN, a narrow band-gap channel consisting of a Ga₁₋ₓInₓN ternary alloy (0.04≦x≦1) or, alternatively, an InGaN/GaN superlattice (SL) formed on the GaN back-barrier buffer layer opposite to the substrate, a GaN spacer layer formed on said narrow band-gap channel layer opposite to the GaN back-barrier buffer layer and a carrier supplying barrier layer consisting of an Al_{1-y}In_{y}N (0.14<x≦0.20) ternary alloy formed on said GaN spacer layer opposite to the narrow band-gap channel. The GaN spacer layer and the narrow band-gap channel together form a composite channel layer. A 2DEG region is contained in the composite channel layer. Due to the large lattice mismatch between InGaN and GaN, the thickness of the InGaN layer in said SL should be less than its critical thickness. The thickness and number of InGaN layers in the SL are ≦0.5 nm and 1-5, respectively. A preferred thickness of the GaN spacer layer between the narrow band-gap channel and AlInN carrier supplying barrier is 0.5-1.5 nm. The GaN spacer layer reduces a roughness of the carrier supplying barrier-channel interface while the InGaN/GaN SL reduces or eliminates any alloy disorder in the channel. It results in improved electron mobility in the DHFET channel. A potential barrier preventing 2DEG leakage from the DHFET channel is formed at the InGaN/GaN SL channel—GaN back-barrier buffer interface.

These and other features and advantages of the invention would be apparent to those skilled in the art from the following detailed description, taken together with the accompanying drawings.

### BRIEF DESCRIPTION OF THE DRAWINGS

FIG. 1 is a cross-sectional view of a prior art InGaN-based DHFET.

FIG. 2 is a cross-sectional view of a first embodiment of an InGaN-based DHFET according to the present invention.

FIG. 3 is a plot of the GaInGaN critical thickness calculated as a function of In concentration in alloy.

FIG. 4 illustrates an improvement of 2DEG mobility in the InGaN-based DHFET constructed in accordance with this invention with increasing GaN spacer thickness. The 2DEG sheet charge density as a function of the GaN spacer thickness is shown along with mobility.

FIG. 5 is a simulated conduction band diagram of an InGaN-based DHFET with a GaN spacer in accordance with this invention.

FIG. 6 is a cross-sectional view of a second embodiment of an InGaN-based DHFET according to the present invention.

FIG. 7 is a simulated conduction band diagram of an InGaN-based DHFET with an InGaN/GaN SL in accordance with this invention.

FIG. 8 is a flowchart illustrating method of creating the InGaN-based DHFET in accordance with the present invention.

### DETAILED DESCRIPTION OF THE INVENTION

A description of example embodiments of the invention follows.

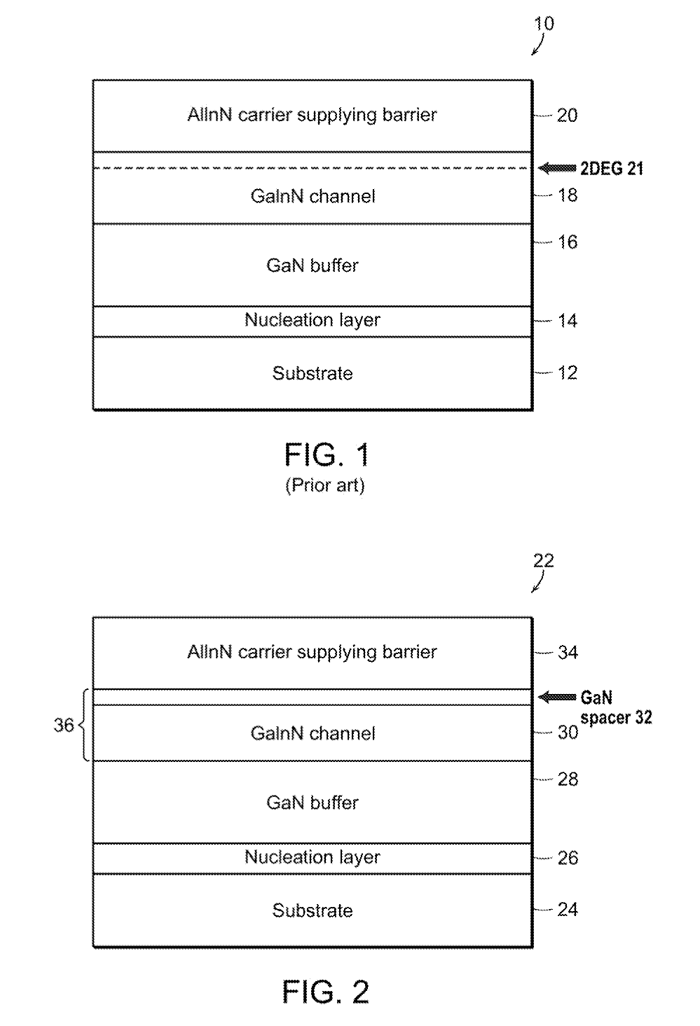

FIG. 1 illustrates a prior art InGaN-based DHFET structure 10 that comprises a substrate 12, a nucleation layer 14 adjacent to the substrate, a GaN back-barrier buffer layer 16 adjacent to the nucleation layer 14 opposite the substrate 12, a InₓGa₁₋ₓN (0.04<x≦0.1) channel layer 18 adjacent to the GaN buffer layer 16, opposite the substrate 12, and an Al_{1-y}In_{y}N (0.14<y≦0.2) carrier-supplying layer 20 adjacent to the InₓGa₁₋ₓN 18, opposite the GaN back-barrier buffer layer 16. A 2DEG region 21 is at the interface between InₓGa₁₋ₓN channel layer 18 and Al_{1-y}In_{y}N carrier-supplying layer 20.

FIG. 2 shows one embodiment of the InGaN-based DHFET 22 constructed in accordance with the present invention. It comprises a substrate 24, a nucleation layer 26 adjacent to the substrate 24, a GaN back-barrier buffer layer 28 adjacent to the nucleation layer 26, opposite the substrate 24, a InₓGa₁₋ₓN channel layer 30 adjacent to the GaN back-barrier buffer layer 28, opposite the nucleation layer 26, a GaN spacer layer 32 adjacent to the InₓGa₁₋ₓN channel layer 30, opposite the GaN back-barrier buffer layer 28 and an Al_{1-y}In_{y}N carrier-supplying barrier layer 34 adjacent to the GaN spacer layer 32, opposite the Ga₁₋ₓInₓN channel layer 30. InₓGa₁₋ₓN channel layer 30 and GaN spacer layer 32 together form composite channel layer 36. A 2DEG region is contained within composite channel layer 36.

The substrate 24 can be made of different materials, such as a sapphire, silicon carbide, silicon or GaN. Substrate 24 can be semi-insulating or conductive. The nucleation layer 26 can be included on the substrate 24 to reduce the lattice mismatch between the substrate 24 and the GaN back-barrier buffer layer 28. It can be made of different materials such as InGaN, GaN, AN and their alloys. The thickness of the nucleation layer 26 is approximately 10-500 nm although other thicknesses can be used. The GaN back-barrier buffer layer 28 can be undoped or intentionally doped with such impurities as iron (Fe), carbon (C) or other elements to induce the insulating properties in GaN. The thickness of the GaN back-barrier buffer layer 28 is between about 0.1 and about 20 μm. In one of the preferred embodiments in FIG. 2, the GaN back-barrier buffer layer 28 is about 2 μm thick. Alternatively, the back-barrier buffer layer 28 can be made of Inₓ_{₁}Ga₁₋ₓ_{₁}N (where x₁<x in InₓGa₁₋ₓN channel layer) or Al_{z}Ga _{1-z}N (0≦z≦0.1). The GaN back-barrier buffer layer 28 provides an electrical insulation and electron confinement for the channel layer 30 from the substrate 24.

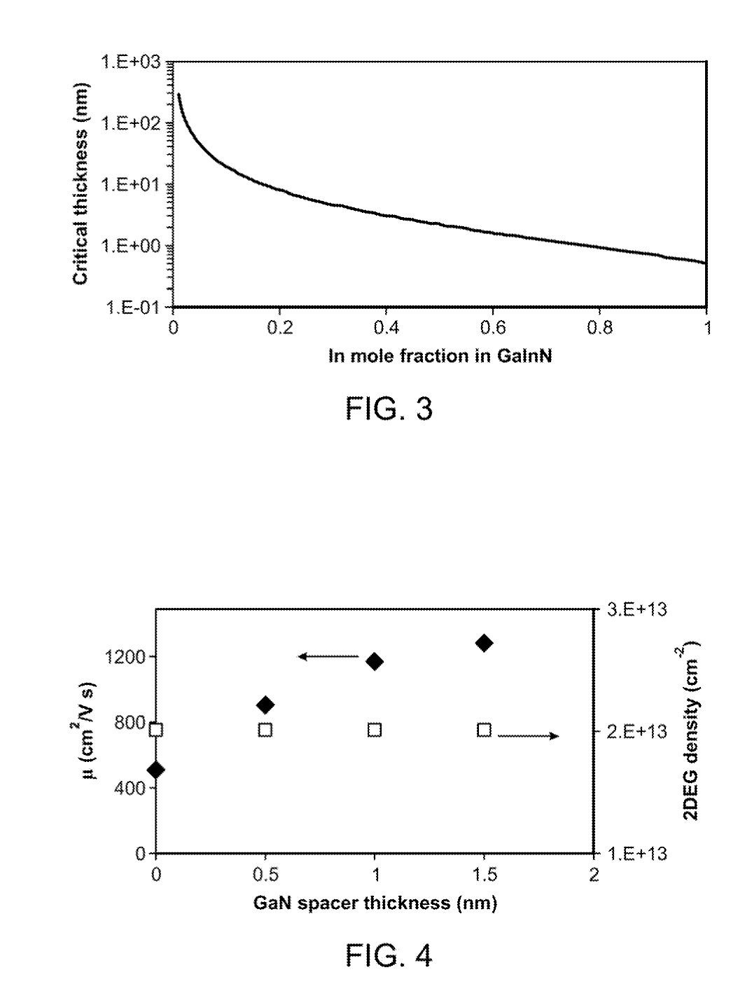

The InₓGa₁₋ₓN channel layer 30 according to the present invention can be undoped or intentionally doped with such an impurity as silicon (Si) or other n-type impurities to improve the electron transport properties of the channel. The thickness and composition of said InₓGa₁₋ₓN channel layer 30 are between about 0.5 and about 60 nm, and 0.04<x≦1, respectively. The InₓGa₁₋ₓN channel layer 30 is lattice mismatched with the GaN back-barrier buffer layer 28. Therefore, a construction of the InₓGa₁₋ₓN channel on top of the GaN back-barrier buffer layer 28 creates a mechanical stress the magnitude of which depends on the In concentration (x) and thickness of the InₓGa₁₋ₓN channel layer 30. If the stress relaxes, the structural defects are formed leading to the inferior properties of the channel. The stress relaxation is associated with so-called critical thickness of the InₓGa₁₋ₓN channel layer 30 for a given In concentration. FIG. 3 reports the critical thickness for the InₓGa₁₋ₓN channel layer 30 as a function of the In concentration in the alloy. This figure illustrates a range of the thicknesses below the critical one available for the InGaN-based DHFET construction in accordance with this invention.

The thickness of the GaN spacer layer 32 according to this invention is approximately 0.5-1.5 nm. FIG. 4 illustrates an improvement of a 2DEG mobility in the InGaN-based DHFET fabricated in accordance with this invention with increasing GaN spacer layer 32 thickness. The 2DEG sheet charge density in the DHFET is plotted along with mobility. The 2DEG mobility and density are measured at room temperature using Hall effect in the Van der Pauw configuration. Mobility increases from about 500 to almost 1300 cm²/V·s, more than 2.5 times while the density is unchanged, when the GaN spacer layer 34 thickness increases from about 0 to about 1.5 nm. The improvement in mobility levels off when the thickness increases over 1.5 nm. This thickness is found to be sufficient to flatten out a surface of the InGaN channel layer 32 and to form a smooth interface with a carrier supplying layer 34. The root mean square (Rms) roughness of the interface is approximately≦0.3 nm. The 2DEG mobility improves as the electron scattering by an interface roughness is eliminated.

The thickness of the Al_{1-y}In_{y}N carrier supplying barrier layer 34 is approximately 3-15 nm, although other thicknesses can be used. The preferred composition is approximately 0.18. This composition results in the lattice match conditions with the GaN back-barrier buffer layer. However, the composition can be varied within 0-0.2 range still allowing a synthesis of the device quality carrier supplying layer. Alternatively, the carrier-supplying barrier layer 34 can be made of Al_{z}_{₁}Ga_{1-z}_{₁}N (0.1≦z₁≦1). The drain, source and gate contacts of DHFET device are formed on top of the carrier-supplying layer 34.

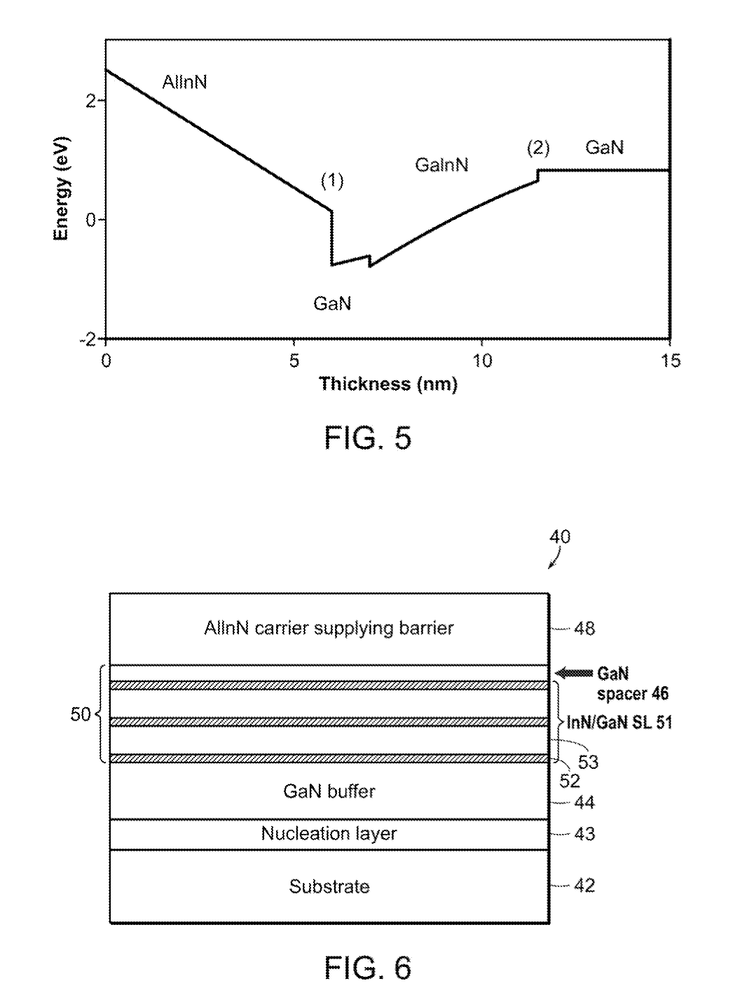

FIG. 5 shows a simulated conduction band diagram of the InGaN-based DHFET with a GaN spacer layer 32 in accordance with the embodiment of this invention shown in FIG. 2. The band diagram is shown at zero bias and is taken from a surface of the AlInN carrier-supplying layer 34 vertically through the carrier-supplying layer 34, GaN spacer layer 32, InGaN channel layer 30 and GaN back-barrier buffer layer 28. The thicknesses for this band diagram are chosen to be 6, 1 and 4.5 nm for the carrier-supplying layer 34, GaN spacer layer 32 and InGaN channel layer 30, respectively. Due to the spontaneous and piezoelectric polarization charges pointing out to the same direction, the bottom of the conduction band in the InGaN channel layer 30 and GaN spacer layer 32 is bent downwards with respect to the Fermi level position (0 eV). It results in the formation of a 2DEG region InGaN. The potential barrier (2) protects the 2DEG region 36 from moving away from the DHFET channel.

FIG. 6 shows another embodiment 40 of the DHFET constructed in accordance with the present invention. It has a substrate 42, nucleation layer 43, GaN back-barrier buffer layer 44 , GaN spacer layer 46, InGaN/GaN SL 51 and AlInN carrier-supplying barrier layer 48. GaN spacer layer 46 and InGaN/GaN SL 51 together form composite channel layer 50. A 2DEG region InGaN is contained in composite channel layer 50. The InGaN has a large lattice mismatch with GaN and its thickness is limited to the critical thickness of about 0.5 nm as shown in FIG. 3. The thickness of the GaN layer inside the SL 51 can be varied from between about 0.5 and about 5 nm, although other thicknesses can be used. The number of InGaN—GaN pairs in the SL 51 can be varied between 1 and 5. FIG. 6 shows 3 InGaN layers 52 and 2 intermediate GaN layers 53. These 5 layers form SL 51 having 2.5 pairs (3 unfinished pairs).

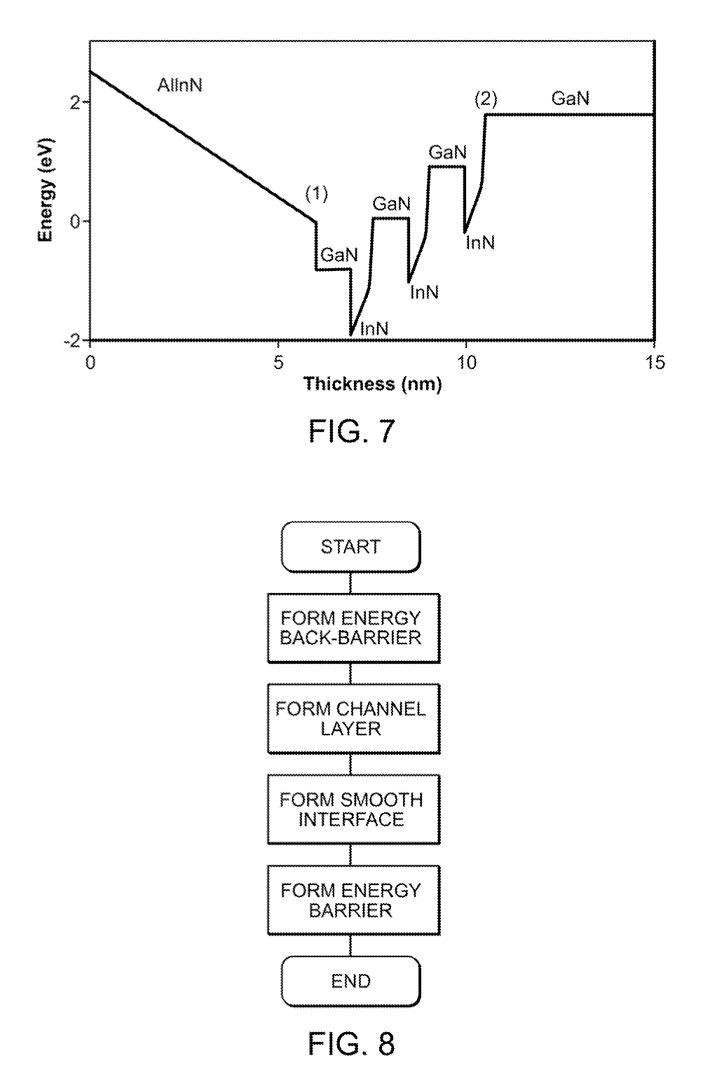

FIG. 7 shows a simulated conduction band diagram of the InGaN-based DHFET with the InGaN/GaN SL 51 in accordance with the embodiment of this invention shown in FIG. 6. The band diagram is shown at zero bias and is taken from a surface of the AlInN carrier supplying barrier layer 48 vertically through the carrier-supplying layer, GaN spacer layer 32, InGaN/GaN SL channel layer 52 and GaN back-barrier buffer layer 28. In this band diagram, the thicknesses for the AlInN carrier-supplying layer 48 and GaN spacer layer 32 are the same with that used in FIG. 5. In one embodiment, the thicknesses of the InGaN layer 52 and GaN layer 53 in the SL are 0.5 and 1 nm, respectively. The number of the InGaN—GaN pairs in SL is 2.5. The strong piezoelectric and spontaneous polarization charges at all AlInN—GaN and InGaN—GaN interfaces bend the bottom of the conduction band downwards below the Fermi level (0 eV) creating the 2DEG region 36 at or near the GaN spacer layer 46—InGaN—GaN SL 51 interface (1) and confining the 2DEG region, InGaN similar to the DHFET 22 in accordance with the first embodiment of the present invention. The use of InGaN and GaN thin layers in the channel of DHFET enables embodiments of the present invention to eliminate the negative impact of electron scattering due to the alloy disorder on the electron mobility in the InGaN-based channels.

The drain, source and gate contacts of DHFET device 40 with the InGaN/GaN SL channel are formed on top of the AlInN carrier supplying barrier layer 48, similar to that of the first embodiment of the present invention.

In the embodiment illustrated in FIG. 6, the thin InGaN layers are used to construct the InGaN/GaN SL. In order to keep InGaN from decomposing during the subsequent growth, it is essential to preserve a two-dimensional (2D) nature of InGaN film. Metal-organic chemical vapor deposition (MOCVD) of a DHFET wafer at relatively high temperature for InGaN in a range of between about 600 and about 700° C. and at relatively low temperature for the GaN spacer layer and AlInN carrier supplying barrier layer in a range of between about 700 and about 800° C. can be utilized to achieve this goal. The growth temperatures are measured on the surface of the wafer carrier using optical pyrometery. Such deposition method results in a pronounced delay in formation of roughness in InGaN films thus improving their thermal stability.

The method embodiments of the present invention are illustrated in FIG. 8. As shown, a method according to the present invention includes forming an energy back-barrier below the channel layer, forming channel layer, forming a smooth interface and forming an energy barrier opposite the back-barrier. The energy barriers prevent the electrons moving away from the channel layer. Forming smooth interface between the channel and barrier layers eliminates the electron scattering by interface roughness and improves the DHFET characteristics.

The relevant teachings of all patents, published applications and references cited herein are incorporated herein by reference in their entirety.

While this invention has been particularly shown and described with references to example embodiments thereof, it will be understood by those skilled in the art that various changes in form and details may be made therein without departing from the scope of the invention encompassed by the appended claims.

What is claimed is:

1. A double-heterojunction field effect transistor, comprising:
a) a substrate;
b) a GaN back-barrier buffer layer on said substrate;
c) a composite channel layer, the composite channel layer including,
i) a InₓGa₁₋ₓN channel layer on said GaN back-barrier buffer layer opposite said substrate, and
ii) a GaN spacer layer on said InₓGa₁₋ₓN channel layer opposite said GaN back-barrier buffer layer, wherein a two-dimensional electron gas region is contained within the composite channel layer; and
d) a carrier-supplying barrier layer on said GaN spacer layer opposite InₓGa₁₋ₓN channel layer.

2. The double-heterojunction field effect transistor of claim 1, wherein the carrier-supplying barrier layer comprises Al_{1-y}In_{y}N.

3. The double-heterojunction field effect transistor of claim 2, wherein the carrier-supplying barrier layer comprises of Al_{z}_{₁}Ga_{1-z}_{₁}N, wherein 0.1≦z₁≦1.

4. The double-heterojunction field effect transistor of claim 1, wherein said GaN spacer layer is less than approximately 1.5 nm.

5. The double-heterojunction field effect transistor of claim 1, wherein the channel layer comprises of InₓGa₁₋ₓN, wherein 0.04≦x≦1.

6. The double-heterojunction field effect transistor of claim 2, wherein the carrier-supplying layer is comprised of Al_{1-y}In_{y}N, wherein 0<y≦0.20.

7. The double-heterojunction field effect transistor of claim 1, wherein the back-barrier buffer layer comprises of Al_{z}Ga_{1-z}N, wherein 0≦z≦0.1.

8. A double-heterojunction field effect transistor , comprising:
a) a substrate;
b) a GaN back-barrier buffer layer on said substrate;
c) a composite channel layer, the composite channel layer including,
i) an InGaN/GaN superlattice channel layer on said GaN back-barrier buffer layer opposite said substrate, and
ii) a GaN spacer layer on said superlattice channel layer opposite said GaN back-barrier buffer layer, wherein a two-dimensional electron gas region is contained within the composite channel layer; and
d) a carrier-supplying barrier layer on said GaN spacer layer opposite the superlattice channel layer.

9. The double-heterojunction field effect transistor of claim 8, wherein the carrier-supplying barrier layer comprises Al_{1-y}In_{y}N.

10. The double-heterojunction field effect transistor of claim 8, wherein said InGaN/GaN superlattice channel layer includes a layer of InGaN having a thickness greater than about 0.0 nm and equal to or less than about 0.5 nm.

11. The double-heterojunction field effect transistor of claim 8, wherein said InGaN/GaN superlattice includes GaN having a thickness of between about 0.5 and about 5 nm.

12. The double-heterojunction field effect transistor of claim 8, wherein the number of InGaN—GaN pairs in said InGaN/GaN SL is between about 1 and about 5.

13. A method of metal-organic chemical vapor deposition of a double-heterojunction field effect transistor wafer having an InGaN—GaN superlattice channel, which includes a deposition of an InGaN layer at a growth temperature in a range of between about 600° C. and about 700° C., a deposition of a GaN spacer layer and a carrier-supplying barrier layer on a surface of the double-heterojunction field effect transistor at a growth temperature in a range of between about 700° C. and about 800° C.

14. A method of manufacturing a double heterojunction field effect comprising the step of forming a smooth interface, with an Rms roughness of equal to or less than about 0.3 nm, between a channel layer and a carrier-supplying barrier layer opposite a GaN back-barrier buffer layer that is below said channel layer of the double heterojunction field effect transistor, to thereby essentially eliminate electron scattering in the channel.

15. A method of manufacturing a double heterojunction field effect transistor, comprising the step of forming a channel layer consisting essentially of an InGaN/GaN superlattice being essentially free of any alloy disorder that would cause alloy scattering of electrons in the channel.
